(19) United States
(12) Patent Application Publication
(10) Pub. No.: US 2016/0276609 A1
(43) Pub. Date: Sep. 22, 2016

(54) DYE-SENSITIZED SOLAR CELL

(71) Applicants: Tamotsu HORIUCHI, Shizuoka (JP); Tohru YASHIRO, Kanagawa (JP); Hiroshi SEGAWA, Tokyo (JP); Satoshi UCHIDA, Tokyo (JP)

(72) Inventors: Tamotsu HORIUCHI, Shizuoka (JP); Tohru YASHIRO, Kanagawa (JP); Hiroshi SEGAWA, Tokyo (JP); Satoshi UCHIDA, Tokyo (JP)

(73) Assignee: Ricoh Company, Ltd., Tokyo (JP)

(21) Appl. No.: 15/036,135

(22) PCT Filed: Nov. 26, 2014
(86) PCT No.: PCT/JP2014/081914

§ 371 Date: May 12, 2016

(30) Foreign Application Priority Data
Nov. 26, 2013 (JP) 2013-244059
Aug. 29, 2014 (JP) 2014-175134

(51) Int. Cl. H01L 51/42; H01G 9/20; H01L 51/44

(52) U.S. Cl. CPC H01L 51/4226; H01L 51/442; H01G 9/2027; H01G 9/2013; H01L 2251/303; H01L 51/0083

(57) ABSTRACT

A dye-sensitized solar cell, which contains: a transparent electroconductive film substrate; a first electrode provided with a layer of an electron-transporting compound, which is composed of nano particles each coated with a sensitizing dye; a charge transfer layer; a hole transport layer; and a second electrode, wherein the first electrode, the charge transfer layer, the hole transport layer, and the second electrode are provided in this order on the transparent electroconductive film substrate, and wherein the charge transfer layer contains a metal complex salt, and the hole transport layer contains a polymer.

### TECHNICAL FIELD

The present invention relates to a dye-sensitized solar cell.

### BACKGROUND ART

Recently, an importance of solar cells has increased as an alternative energy source to fossil fuels, and as a countermeasure for global warming. However, current solar cells, represented by silicon solar cells, are currently expensive, and this high cost is a factor for preventing popularization of solar cells.

Therefore, researches and developments of various low cost solar cells have been conducted. Among them, there is a high expectation for a dye-sensitized solar cell, which has been reported by Graetzel et al. from Ecole Polytechnique Federale de Lausanne, to be applied for practical use (see, for example, PTL 1, and NPLs 1 and 2). This solar cell has a structure containing a porous metal oxide semiconductor provided on a transparent electroconductive glass substrate, a dye adsorbed on a surface thereof, an electrolyte having a redox couple, and a counter electrode. Graetzel and others have significantly improved a photoelectric conversion efficiency of the solar cell by making a metal oxide semiconductor electrode, such as titanium oxide, porous to thereby increase a surface area thereof, and adsorbing each molecular of a ruthenium complex as a dye.

A printing method can be applied for a production method of the cell, and expensive production equipments are not required for production of the cell. Therefore, reduction in a production cost is expected. However, this solar cell contains iodine and a volatile solvent, and there are problems that the power generation efficiency is reduced due to deterioration of an iodide-radox system, or the electrolyte is evaporated or leaked.

As for the one solves these problems, the following solid dye-sensitized solar cells have been reported.

1) A solid dye-sensitized solar cell using an inorganic semiconductor (see, for example, NPLs 3 and 4)
2) A solid dye-sensitized solar cell using a low-molecular weight organic hole-transporting material (see, for example, PTL 2, and NPLs 5 and 6)
3) A solid dye-sensitized solar cell using an electroconductive polymer (see, for example, PTL 3 and NPL 7)

In the solar cell disclosed in NPL 3, copper iodide is use as a constitutional material of a p-type semiconductive layer. It has been known that the photoelectric conversion efficiency of this solar cell is reduced in half within a few hours due to deterioration caused by growth of crystal grains of copper iodide, through the solar cell exhibits a relatively excellent photoelectric conversion efficiency just after the production thereof. In the solar cell disclosed in NPL 4, therefore, crystallization of copper iodide is prevented by adding imidazolinium thiocyanate. It is however not sufficient to prevent the crystallization.

The solid dye-sensitized solar cell using the organic hole-transporting material, disclosed in NPL 5, has been reported by Hagen et al., and then has been developed by Graetzel et al. (see NPL 6).

In the solid dye-sensitized solar cell using the triphenylamine compound disclosed in PTL 2, a charge transport layer is formed by vacuum depositing the triphenylamine compound. Therefore, the triphenylamine compound cannot reach the inner area of the porous of the porous semiconductor, and therefore only a low conversion efficiency is achieved.

In the example disclosed in NPL 6, a composition of nano titania particles and a hole-transporting material is obtained by dissolving the spiro hole-transporting material in an organic solvent, and applying the resulting solution through spin coating. An optimal value of a film thickness of the nano titania particles in the solar cell is specified as about 2 μm, which is extremely thin compared to the range of 10 μm to 20 μm in the case where the iodine electrolyte is used. Therefore, an amount of the dye adsorbed on the titanium oxide is small, and it is difficult to perform light absorption or generation of carrier, sufficiently. The properties thereof do not reach the level of the solar cell using the electrolyte. The reason why the film thickness of the nano titania particles is 2 μm is because penetration of the hole-transporting material cannot be carried out sufficiently, as the film thickness increases.

As for a solid solar cell to which an electroconductive polymer is used, Yanagida et al. from Osaka University have reported a solar cell using polypyrrol (see NPL 7). This solar cell also exhibits a low conversion efficiency. In the solid dye-sensitized solar cell using the polythiophene derivative disclosed in PTL 3, a charge transfer layer is provided using electrolytic polymerization above a porous titanium oxide electrode to which a dye is adsorbed. However, there are problems that the dye is detached from the titanium oxide, or the dye is decomposed.

As mentioned above, it is the current situation that any of conventional solid dye-sensitized solar cells has not had satisfactory properties.

### CITATION LIST

### Patent Literature

PTL 1: Japanese Patent (JP-B) No. 2664194
PTL 2: Japanese Patent Application Laid-Open (JP-A) No. 11-144773
PTL 3: JP-A No. 2000-106223
PTL 4: International Publication No. WO07/100095

### Non-Patent Literature

NPL 1: Nature, 353 (1991) 737
NPL 2: J. Am. Chem. Soc., 115 (1993) 6382
NPL 3: Semicond. Sci. Technol., 10 (1995) 1689
NPL 4: Electrochemistry, 70 (2002) 432
NPL 5: Synthetic Metals, 89 (1997) 215
NPL 6: Nature, 398 (1998) 583
NPL 7: Chem. Lett., (1997) 471
NPL 8: Nano. Lett., 1 (2001) 97

### SUMMARY OF INVENTION

### Technical Problem

The present invention aims to solve the aforementioned problems, and to provide a solid dye-sensitized solar cell, which has excellent long-term stability compared to the cells in the conventional art, and is also excellent in productivity thereof.

### Solution to Problem

As a result of the studies diligently performed in order to solve the aforementioned problems, it has been found that a high performance dye-sensitized solar cell can be provided and the present invention is accomplished.

The aforementioned problems can be solved by the “dye-sensitized solar cell” having the following structure (1) of the present invention.

(1) A dye-sensitized solar cell, containing:

a transparent electroconductive film substrate;

a first electrode provided with a layer of an electron-transporting compound, which is composed of nano particles each coated with a sensitizing dye;

a charge transfer layer;

a hole transport layer; and

a second electrode,

wherein the first electrode, the charge transfer layer, the hole transport layer, and the second electrode are provided in this order on the transparent electroconductive film substrate, and

wherein the charge transfer layer contains a metal complex salt, and the hole transport layer contains a polymer.

### Advantageous Effects of Invention

The dye-sensitized solar cell of the present invention can achieve a dye-sensitized solar cell of excellent properties, as the dye-sensitized solar cell of the present invention has the structure described in (1) above. Specifically, the present invention exhibits excellent effects that a solid dye-sensitized solar cell having excellent long-term stability compared to conventional solar cells, and is also excellent in productivity.

### BRIEF DESCRIPTION OF DRAWINGS

FIG. 1 is a schematic diagram illustrating one example of a structure of the solar cell of the present invention.

FIG. 2 is an IR spectrum of tris(2,2′-bipyridyl)cobalt (II) perchlorate obtained in Synthesis Example 1.

FIG. 3 is an IR spectrum of tris(2,2′-bipyridyl)cobalt (III) perchlorate obtained in Synthesis Example 2.

FIG. 4 is an IR spectrum of tris(2,2′-bipyridyl)cobalt (II) tetracyanoborate obtained in Synthesis Example 3.

FIG. 5 is an IR spectrum of tris(2,2′-bipyridyl)cobalt (III) tetracyanoborate obtained in Synthesis Example 4.

### DESCRIPTION OF EMBODIMENTS

The present invention is specifically explained hereinafter.

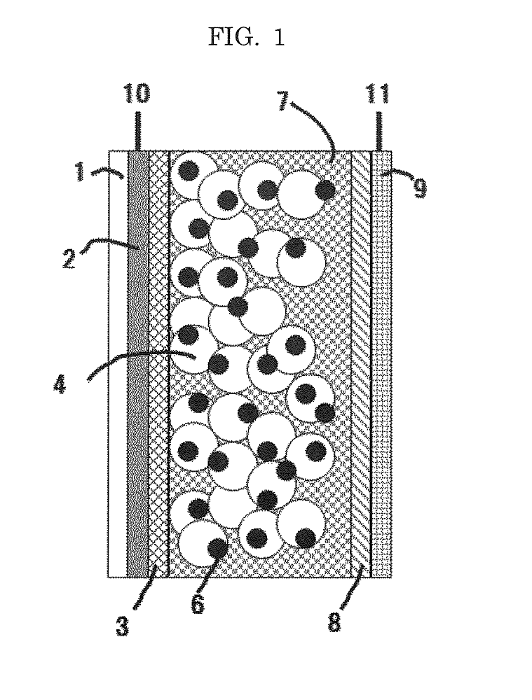

The structure of the dye-sensitized solar cell is explained based on FIG. 1.

Note that, FIG. 1 is a cross-sectional view of the dye-sensitized solar cell.

In the embodiment illustrated in FIG. 1, the dye-sensitized solar cell has a structure where an electrode 2 is provided on a substrate 1, an electron transport layer 5 composed of a dense electron transport layer 3, and a particulate electron transport layer 4, a photosensitizer 6 coating the electron transport layer, a transport layer composed of a charge transfer layer 7, and a hole-transporting material layer 8, and a second electrode 9 are sequentially provided.

### <Electron-Collecting Electrode>

The electron-collecting electrode 2 for use in the present invention is not particularly limited as long as it is formed of an electroconductive material that is transparent to visible rays. As for the electron-collecting electrode 2, a typical photoelectric conversion element, or a conventional electrode used in a liquid crystal panel can be used.

Examples thereof include indium-tin oxide (referred to as ITO hereinafter), fluorine-doped tin oxide (referred to as FTO hereinafter), antimony-doped tin oxide (referred to as ATO hereinafter), indium-zinc oxide, niobium-titanium oxide, and grapheme. Each of them may form a single layer, or two or more of them form a laminate.

A thickness of the electron-collecting electrode is preferably 5 nm to 100 more preferably 50 nm to 10 μm.

In order to maintain a certain hardness of the electron-collecting electrode, moreover, the electron-collecting electrode is preferably provided on a substrate formed of a material that is transparent to visible light. As for the substrate, for example, glass, a transparent plastic plate, a transparent plastic film, or inorganic transparent crystal is used. A conventional substrate integrated with the electron-collecting electrode can be also used. Examples thereof include FTO coated glass, ITO coated glass, zinc oxide/aluminum coated glass, an FTO coated transparent plastic film, and an ITO coated transparent plastic film.

Moreover, used may be a substrate, such as a glass substrate, on which a transparent electrode, in which tin oxide or indium oxide is doped with a cation or anion having a different atomic value, or a metal electrode having a structure to pass through light, such as in the form of a mesh, or stripes, is provided. These may be used alone, or a mixture, or a laminate.

Moreover, a metal lead wire may be used for the purpose of reducing the resistance of the substrate 1.

Examples of a material of the metal lead wire include a metal, such as aluminum, copper, solver, gold, platinum, and nickel. The metal lead wire is provided on the substrate by vapor deposition, sputtering, or contact bonding, followed by providing ITO or FTO thereon.

### <Electron Transport Layer>

In the solar cell of the present invention, a thin film formed of a semiconductor is provided as the electron transport layer 5 on the electron-collecting electrode 2.

The electron transport layer 5 preferably has a single or multi layered structure, in which a dense electron transport layer 3 is formed on the electron-collecting electrode 2, and a porous electron transport layer 4 is formed on the dense electron transport layer 3.

The dense electron transport layer 3 is formed for the purpose of preventing electronic contact between the electron-collecting electrode 2 and the charge transfer layer 7. Therefore, a pin-hole or crack may be formed in the dense electron transport layer 3 as long as the electron-collecting electrode and the hole transport layer are not physically in contact with each other.

There is no restriction in a thickness of the dense electron transport layer, but the thickness thereof is preferably 10 nm to 1 μm, more preferably 20 nm to 700 nm.

Note that, the term “dense” used in association with the electron transport layer 5 means that inorganic oxide semiconductor is loaded at higher density compared to the loading density of the semiconductor particles in the electron transport layer 5.

The porous electron transport layer 4 formed on the dense electron transport layer 3 may be a single layer or a multi-layer.

In case of the multi-layer, dispersion liquids containing semiconductor particles having different particle diameter in each layer may be applied to give multiple layers, or coating layers each having a different type of a semiconductor, or a different composition of a resin and additives may be provided to give multiple layers.

The multi-layer coating is an effective method when a thickness of a coated layer obtained by a one coating is insufficient.

Typically, an amount of the photosensitizing compound carried per unit projected area increases, as a thickness of the electron transport layer increases. Therefore, a capturing rate of light is increased. However, a loss due to charge recombination increases, as a diffusion length of the injected electron increases. Accordingly, a thickness of the electron transport layer is preferably 100 nm to 100 μm.

The semiconductor is not particularly limited, and can be selected from conventional semiconductors known in the art.

Specific examples thereof include a single semiconductor (e.g., silicon, and germanium), a compound semiconductor (e.g., chalcogenide of a metal), and a compound having a perovskite structure.

Examples of the chalcogenide of a metal include: oxide of titanium, tin, zinc, iron, tungsten, zirconium, hafnium, strontium, indium, cerium, yttrium, lanthanum, vanadium, niobium, or tantalum; sulfide of cadmium, zinc, lead, silver, antimony, or bismuth; selenide of cadmium, or lead; and telluride of cadmium.

As for other compound semiconductors, preferred are phosphide of zinc, gallium, indium, or cadmium, gallium arsenide, copper-indium-selenide, and copper-indium-sulfide.

As for the compound having a perovskite, preferred are strontium titanate, calcium titanate, sodium titanate, barium titanate, and potassium niobate.

Among them, oxide semiconductor is preferable, and titanium oxide, zinc oxide, tin oxide, and niobium oxide are particularly preferable. These may be used alone, or a mixture. A crystal structure of any of these semiconductors is not particularly limited, and the crystal structure thereof may be a single crystal, polycrystal, or amorphous.

A size of the semiconductor particles is not particularly limited, but the average particle diameter of the primary particle thereof is preferably 1 nm to 100 nm, more preferably 5 nm to 50 nm.

Moreover, the efficiency can be improved by mixing or stacking semiconductor particles having the larger average particle diameter to scatter incident light. In this case, the average particle diameter of the semiconductor is preferably 50 nm to 500 nm.

A formation method of the electron transport layer is not particularly limited, and examples thereof include a method for forming a thin film in vacuum, such as sputtering, and a wet film forming method.

In view of a production cost, a wet film forming method is preferable. A method where a paste, in which a powder or sol of semiconductor particles is dispersed, is prepared, and the paste is coated on the electron-collecting electrode substrate, is preferable.

In the case where the wet film forming method is used, the coating method is not particularly limited, and coating can be performed in accordance with a conventional method.

As for the coating method, for example, usable are various methods, such as dip coating, spray coating, wire-bar coating, spin coating, roller coating, blade coating, gravure coating, and wet printing (e.g., relief printing, offset printing, gravure printing, intaglio printing, rubber plate printing, and screen printing.

In the case where the dispersion liquid is prepared by mechanical pulverizing, or by means of a mill, the dispersion liquid is formed by dispersing the semiconductor particles alone, or a mixture of the semiconductor particles and a resin, in water or an organic solvent.

Examples of the resin used for this include: a polymer or a copolymer of a vinyl compound (e.g., styrene, vinyl acetate, acrylic acid ester, and methacrylic acid ester), a silicone resin, a phenoxy resin, a polysulfone resin, a polyvinyl butyral resin, a polyvinyl formal resin, a polyester resin, a cellulose ester resin, a cellulose ether resin, a urethane resin, a phenol resin, an epoxy resin, a polycarbonate resin, a polyacrylate resin, a polyamide resin, and a polyimide resin.

Examples of the solvent, in which the semiconductor particles are dispersed, include water, an alcohol-based solvent (e.g., methanol, ethanol, isopropyl alcohol, and α-terpineol), a ketone-based solvent, (e.g., acetone, methyl ethyl ketone, and methyl isobutyl ketone), an ester-based solvent (e.g., ethyl formate, ethyl acetate, and n-butyl acetate), an ether-based solvent (e.g., diethyl ether, dimethoxy ethane, tetrahydrofuran, dioxolane, and dioxane), an amide-based solvent (e.g., N,N-dimethyl formamide, N,N-dimethyl acetoamide, and N-methyl-2-pyrrolidone), a halogenated hydrocarbon-based solvent (e.g., dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene), and a hydrocarbon-based solvent (e.g., n-pentane, n-hexane, n-octane, 1,5-hexadiene, cyclohexane, methylcyclohexane, cyclohexadiene, benzene, toluene, o-xylene, m-xylene, p-xylene, ethyl benzene, and cumene). These may be used alone, or as a mixed solvent by mixing two or more of them.

In order to prevent re-aggregation of the particles, acid (e.g., hydrochloric acid, nitric acid, and acetic acid), a surfactant (e.g., polyoxyethylene(10) octylphenyl ether), or a chelating agent (e.g., acetylacetone, 2-aminoethanol, and ethylene diamine) may be added to the dispersion liquid of the semiconductor particles, or the paste of the semiconductor particles obtained by a sol-gel method.

Moreover, it is also effective to add a thickener, for the purpose of improving the film forming ability.

Examples of the thickener added include: a polymer, such as polyethylene glycol, and polyvinyl alcohol; and a thickener, such as ethyl cellulose.

The semiconductor particles are preferably subjected to baking, microwave radiation, electron beam radiation, or laser beam radiation after the coating, in order to electronically contact to each other, and improve the film strength, or adhesion to the substrate. These treatments may be performed alone, or in combination.

In the case where the baking is performed, the baking temperature is not particularly limited. As there is a case where the resistance of the substrate becomes high or the substrate is melted, when the temperature is excessively high, the baking temperature is preferably 30° C. to 700° C., more preferably 100° C. to 600° C. Moreover, the baking duration is not particularly limited, but the baking duration is preferably 10 minutes to 10 hours.

After the baking, for example, chemical plating using a titanium tetrachloride aqueous solution or a mixed solution with an organic solvent, or electrochemical plating using a titanium trichloride aqueous solution may be performed in order to increase a surface area of the semiconductor particles, or enhance the electron injecting efficiency from the photosensitizing compound to the semiconductor particles.

As for the microwave radiation, microwaves may be applied from the side where the electron transport layer is formed, or from the back side.

The duration of the radiation is not particularly limited, but it is preferably within 1 hour.

A film formed by laminating the semiconductor particles having diameters of several tens nanometers by sintering forms a porous state.

This nano porous structure has an extremely large surface area, and the surface area can be represented by using a roughness factor.

The roughness factor is a value representing the actual area of the inner side of the pours relative to the area of the semiconductor particles applied on the substrate. Accordingly, it is more preferably, as the larger the roughness factor is. The roughness factor is, however, preferably 20 or greater in the present invention, in view of the relationship with the thickness of the electron transport layer.

### <Photosensitizing Compound>

In order to further improve efficiency, the photosensitizing compound 6 is preferably adsorbed on the electron transport layer.

The photosensitizing compound 6 is not particularly limited, provided that it is a compound that is photoexcited upon application of excitation light for use. Specific examples thereof include the following compounds.

Namely, specific examples of the photosensitizing compound include: metal complex compounds disclosed in JP-A Nos. 07-500630, 10-233238, 2000-26487, 2000-323191, and 2001-59062; cumarin compounds disclosed in JP-A Nos. 10-93118, 2002-164089, and 2004-95450, and J. Phys. Chem. C, 7224, Vol. 111 (2007); polyene compounds disclosed in JP-A No. 2004-95450, and Chem. Commun., 4887 (2007); indoline compounds disclosed in JP-A Nos. 2003-264010, 2004-63274, 2004-115636, 2004-200068, and 2004-235052, J. Am. Chem. Soc., 12218, Vol. 126 (2004), Chem. Commun., 3036 (2003), and Angew. Chem. Int. Ed., 1923, Vol. 47 (2008); thiophene compounds disclosed in J. Am. Chem. Soc., 16701, Vol. 128 (2006), and J. Am. Chem. Soc., 14256, Vol. 128 (2006); cyanine dyes disclosed in JP-A Nos. 11-86916, 11-214730, 2000-106224, 2001-76773, and 2003-7359; merocyanine dyes disclosed in JP-A Nos. 11-214731, 11-238905, 2001-52766, 2001-76775, and 2003-7360; 9-aryl xanthene compounds disclosed in JP-A Nos. 10-92477, 11-273754, 11-273755, and 2003-31273; triaryl methane compounds disclosed in JP-A Nos. 10-93118, and 2003-31273; and phthalocyanine compounds and porphyrin compounds disclosed in JP-A Nos. 09-199744, 10-233238, 11-204821, and 11-265738, J. Phys. Chem., 2342, Vol. 91 (1987), J. Phys. Chem. B, 6272, Vol. 97 (1993), Electroanal. Chem., 31, Vol. 537 (2002), JP-A No. 2006-032260, J. Porphyrins Phthalocyanines, 230, Vol. 3 (1999), Angew. Chem. Int. Ed., 373, Vol. 46 (2007), and Langmuir, 5436, Vol. 24 (2008).

Among them, the metal complex compound, the indoline compound, the thiophene compound, and the porphyrin compound are particularly preferably used.

As for the method for adsorbing the photosensitizing compound 6 on the electron transport layer 5, usable are a method where an electron-collecting electrode containing semiconductor particles is immersed in a photosensitizing compound solution or dispersion liquid, and a method where the solution or dispersion liquid is applied onto the electron transport layer to adsorb the photosensitizing compound thereon.

In the former method, dipping, dip coating, roller coating, or air-knife coating can be used. In the latter method, wire-bar coating, slide-hopper coating, extrusion coating, curtain coating, spin coating, or spray coating can be used.

Moreover, the photosensitizing compound may be adsorbed in a supercritical fluid using carbon dioxide.

When the photosensitizing compound is adsorbed, a condensing agent may be used in combination.

The condensing agent may be an agent exhibiting a catalytic function where the photosensitizing compound and the electron transport compound are physically or chemically bonded to a surface of inorganic matter, or an agent that stoichiometrically functions, and effectively transfers exhibits chemical equilibrium.

Moreover, a thiol or hydroxyl compound may be added as a condensation assistant.

Examples of the solvent, in which the photosensitizing compound is dissolved or dispersed, include water, an alcohol-based solvent (e.g., methanol, ethanol, and isopropyl alcohol) a ketone-based solvent (e.g., acetone, methyl ethyl ketone, and methyl isobutyl ketone), an ester-based solvent (e.g., ethyl formate, ethyl acetate, and n-butyl acetate), an ether-based solvent (e.g., diethyl ether, dimethoxy ethane, tetrahydrofuran, dioxolane, and dioxane), an amide-based solvent (e.g., N,N-dimethyl formamide, N,N-dimethyl acetoamide, and N-methyl-2-pyrrolidone), a halogenated hydrocarbon-based solvent (e.g., dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene), and a hydrocarbon-based solvent (e.g., n-pentane, n-hexane, n-octane, 1,5-hexadiene, cyclohexane, methylcyclohexane, cyclohexadiene, benzene, toluene, o-xylene, m-xylene, p-xylene, ethyl benzene, and cumene). These may be used alone, or as a mixed solvent by mixing two or more of them.

There is the photosensitizing compound, which more effectively functions when aggregations between the compounds are prevented, depending on the photosensitizing compound for use. Therefore, an aggregate dissociating agent may be used in combination.

The aggregate dissociating agent is appropriately selected depending on the dye for use, and is preferably a steroid compound (e.g., cholic acid, and chenodeoxycholic acid), long-chain alkyl carboxylic acid, or a long-chain alkyl sulfonic acid. An amount of the aggregate dissociating agent for use is preferably 0.01 parts by mass to 500 parts by mass, more preferably 0.1 parts by mass to 100 parts by mass, relative to 1 part by mass of the dye.

The temperature for adsorbing the photosensitizing compound, or the photosensitizing compound and the aggregate dissociating agent is preferably in the range of −50° C. to 200° C.

Moreover, the adsorbing may be performed with sill standing, or with stirring.

Examples of the stirring, in case of the adsorbing with stirring, include stirring by means of a stirrer, a ball mill, a paint conditioner, a sand mill, Attritor, a disperser, or ultrasonic disperser. However, the stirring is not limited to those listed above.

The time required for the adsorbing is preferably 5 seconds to 1,000 hours, more preferably 10 seconds to 500 hours, and even more preferably 1 minute to 150 hours.

Moreover, the adsorbing is preferably performed in a dark place.

### <Charge Transfer Layer>

In the present invention, the charge transfer layer 7 contains a metal complex salt. The metal complex salt is composed of a metal cation, a ligand, and an anion, and includes all the combinations listed below. Specific examples of the metal cation of the metal complex salt for use in the present invention include cations of chromium, manganese, iron, cobalt, nickel, copper, molybdenum, ruthenium, rhodium, palladium, silver, tungsten, rhenium, osmium, iridium, gold, and platinum. Among them, preferred are cations of cobalt, iron, nickel, and copper.

Specific examples of the ligand for constituting the metal complex salt include the following (A-01) to (A-28). These may be used alone, or in combination.

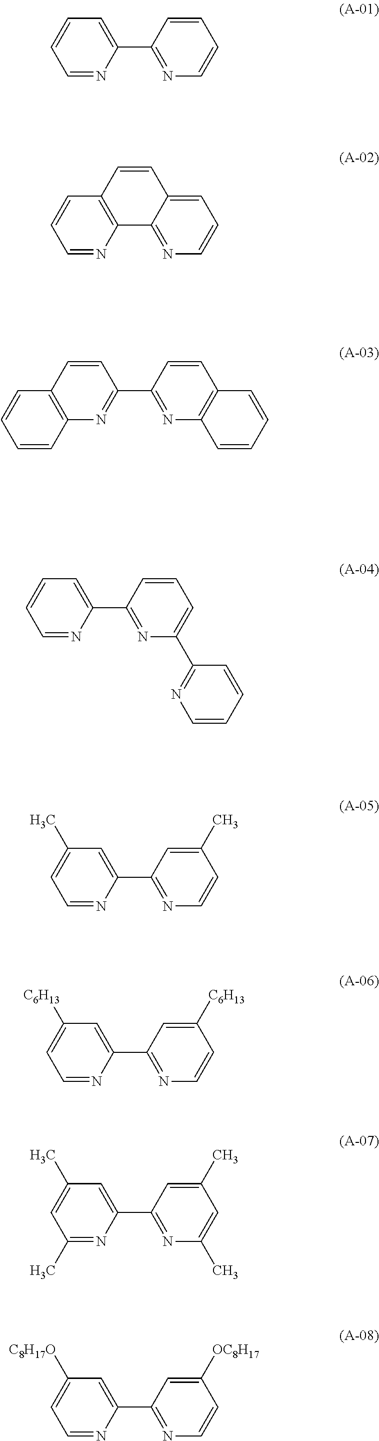

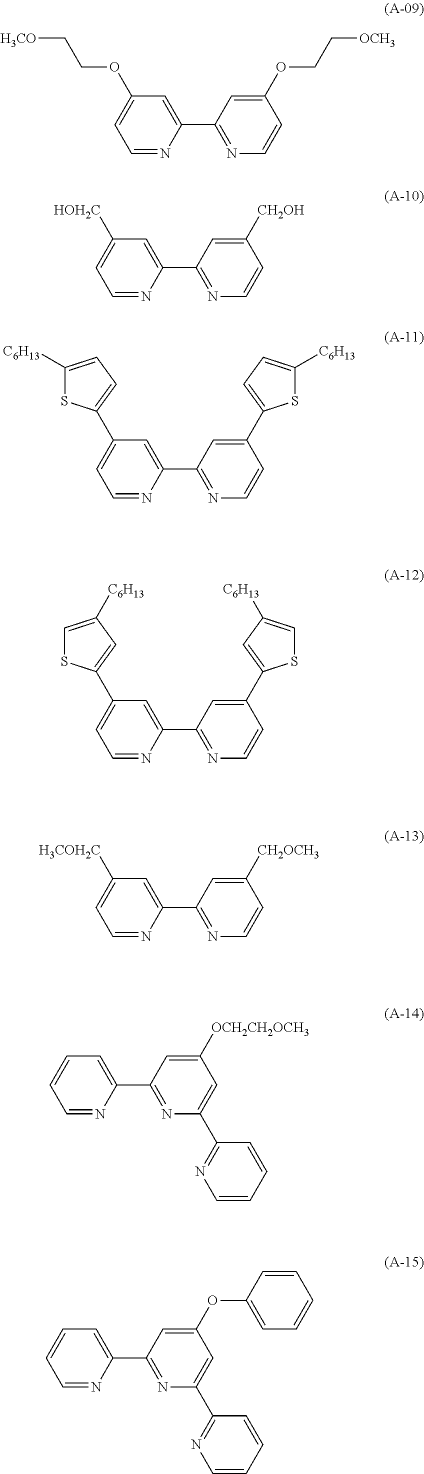

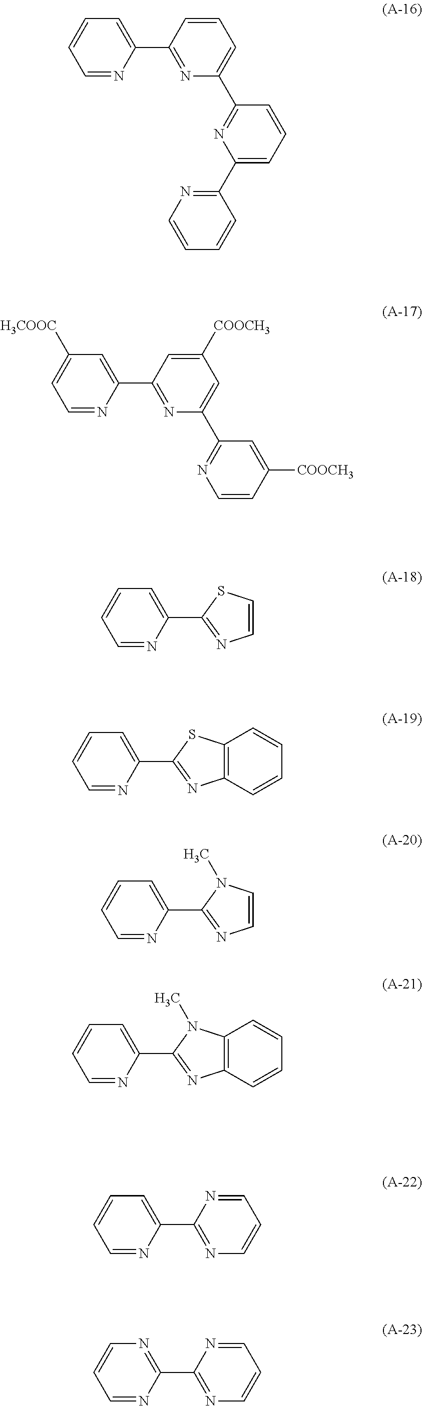

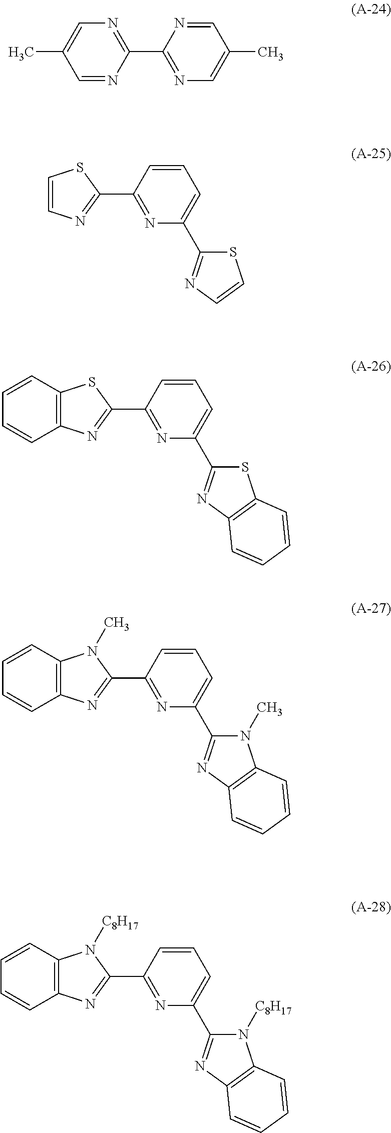

Specific examples of the anion in the metal complex salt include a hydride ion (H⁻), a fluoride ion (F⁻), a chloride ion (Cl⁻), a bromide ion (Br⁻) an iodide ion (I⁻), a hydroxide ion (OH⁻), a cyanide ion (CN⁻), a nitric acid ion (NO₃⁻), a nitrous acid ion (NO₂⁻), a hypochlorous acid ion (ClO⁻), a chlorous acid ion (ClO₂⁻), a chloric acid ion (ClO₃⁻), a perchloric acid ion (ClO₄⁻), a permanganic acid ion (MnO₄⁻), an acetic acid ion (CH₃COO⁻), a hydrogencarbonate ion (HCO₃⁻), a dihydrogen phosphate ion (H₂PO₄⁻), a hydrogen sulfate ion (HSO₄⁻), a hydrogen sulfide ion (HS⁻), a thiocyanic acid ion (SCN⁻), a tetrafluoroboric acid ion (BF₄⁻), a hexafluorophosphate ion (PF₆⁻), a tetracyanoborate ion (B(CN)₄⁻), a dicyanoamine ion (N(CN)₂⁻), a p-toluenesulfonic acid ion (TsO⁻), a trifluoromethyl sulfonate ion (CF₃SO₂⁻), a bis(trifluoromethylsulfonyl)amine ion (N(SO₂CF₃)₂⁻), a tetrahydroxoaluminate ion ([Al(OH)₄]⁻, or [Al(OH)₄(H₂O)₂]⁻), a dicyanoargentate (I) ion ([Ag(CN)₂]⁻), a tetrahydroxochromate (III) ion ([Cr(OH)₄]⁻), a tetrachloroaurate (III) ion ([AuCl₄]⁻), an oxide ion (O₂⁻), a sulfide ion (S₂⁻), a peroxide ion (O₂²⁻), a sulfuric acid ion (SO₄²⁻), a sulfurous acid ion (SO₃²⁻), a thiosulfuric acid ion (S₂O₃²⁻), a carbonic acid ion (CO₃²⁻⁻), a chromic acid ion (CrO₄²⁻), a dichromic acid ion (Cr₂O₇²⁻), a dihydrogen phosphate ion (HPO₄²⁻), a tetrahydroxozincate (II) ion ([Zn(OH)₄]²⁻), a tetracyanozincate (II) ([Zn(CN)₄]²⁻), tetrachlorocuprate (II) ion ([CuCl₄]²⁻), a phosphoric acid ion (PO₄³⁻), a hexacyanoferrate (III) ion ([Fe(CN)₆]³⁻), a bis(thiosulfato)argentat (I) ion ([Ag(S₂O₃)₂]³⁻), and a hexacyanoferrate (II) ion ([Fe(CN)₆]⁴⁻). Among them, preferred are a tetrafluoroboric acid ion, a hexafluorophosphate ion, a tetracyanoborate ion, a bis(trifluoromethylsulfonyl)amine ion, and a perchloric acid ion.

These metal complex salts may be used alone, or as a mixture of the metal complex salts.

In the present invention, a material capable of oxidizing and reducing may be added to the charge transfer layer 7, other than the aforementioned metal complex salt. Specific examples of such a material include: a combination of a metal iodide (e.g., lithium iodide, sodium iodide, potassium iodide, cesium iodide, and calcium iodide) and iodine; a combination of an iodine salt of a quaternary ammonium compound (e.g., tetraalkyl ammonium iodide, pyridinium iodide, imidazolium iodide) and iodide; a combination of a metal bromide (e.g., lithium bromide, sodium bromide, potassium bromide, cesium bromide, and calcium bromide) and bromine; a combination of a bromine salt of a quaternary ammonium compound (e.g., tetraalkyl ammonium bromide, and pyridinium) and bromine; a combination of metal complexes (e.g., ferrocyanic acid salt-ferricyanic acid salt, and ferrocene-ferricinium ion); a combination of sulfur compounds (e.g., sodium polysulfide, and alkyl thiol-alkyldisulfide); a combination of a viologen dye, hydroquinone, and quinone; and an organic radical compound, such as a nitroxide radical compound.

Moreover, it is desirable that an alkali metal salt is added to the charge transfer layer in addition to the aforementioned metal complex salt. Specific examples of the alkali metal salt include: a lithium salt, such as lithium chloride, lithium bromide, lithium iodide, lithium perchlorate, lithium bis(trifluoromethane sulfonyl)diimide, lithium acetate, lithium tetrafluoroborate, lithium pentafluorophosphate, and lithium tetracyanoborate; a sodium salt, such as sodium chloride, sodium bromide, sodium iodide, sodium perchlorate, sodium bis(trifluoromethane sulfonyl)diimide, sodium acetate, sodium tetrafluoroborate, sodium pentafluorophosphate, and sodium tetracyanoborate; and a potassium salt, such as potassium chloride, potassium bromide, potassium iodide, and potassium perchlorate.

In the present invention, an ionic liquid may be added to the charge transfer layer, in addition to the aforementioned metal complex salt.

Specific examples of the ionic liquid include: an imidazolium-based ionic liquid, such as 1-ethyl-3-methylimidazolium bromide, 1-ethyl-3-methylimidazolium hexafluorophosphate, 1-ethyl-3-methylimidazolium tetrafluoroborate, 1-ethyl-3-methylimidazolium tosylate, 1-ethyl-3-methylimidazolium cobalt tetracarbonyl, 1-ethyl-3-methylimidazolium bistrifluoromethane sulfonyl imide, 1-n-hexyl-3-methylimidazolium hexafluorophosphate, 1-n-hexyl-3-methylimidazolium hexafluorophosphate, 1-benzyl-3-methylimidazolium hexafluorophosphate, 1-methyl-3-(3-phenylpropyl)imidazolium hexafluorophosphate, 1-n-hexyl-2,3-dimethylimidazolium hexafluorophosphate, and 1-ethyl-2,3-dimethylimidazolium hexafluorophosphate; a pyridinium-based ionic liquid, such as N-butylpyridinium bromide, N-butylpyridinium hexafluorophosphate, N-butylpyridinium tetrafluoroborate, N-butylpyridinium tosylate, N-butylpyridinium cobalt tetracarbonyl, and N-butylpyridinium bistrifluoromethane sulfonyl dimide; and a pyrrolidinium-based ionic liquid, such as 1-ethyl-1-methylpyrrolidinium bromide, 1-ethyl-1-methylpyrrolidinium hexafluorophosphate, 1-ethyl-1-methylpyrrolidinium tetrafluoroborate, 1-ethyl-1-methylpyrrolidinium tosylate, 1-ethyl-1-methylpyrrolidinium cobalt tetracarbonyl, and 1-ethyl-1-methylpyrrolidinium bistrifluoromethane sulfonyl dimide. Among them, the imidazolinium-based ionic liquid is particularly preferable.

In the present invention, moreover, a basic substance can be added as an additive for improving electrical output of the solar cell. Specific examples of the basic substance include pyridine, 2-methyl pyridine, 4-t-butyl pyridine, 2-picoline, and 2,6-lutidine.

The charge transfer layer 7 is directly formed on the electron transport layer 5 coated with the photosensitizer 6.

A formation method of the charge transfer layer is not particularly limited, and examples thereof include: a method for forming a thin film in vacuum, such as vacuum deposition; and a wet film forming method.

In view of the production cost, the wet film forming method is particularly preferable, and a method for coating on the electron transport layer is preferable. In the wet film forming method is used, examples of the solvent, in which the metal complex salt and various additives are dissolved or dispersed, include a ketone-based solvent, (e.g., acetone, methyl ethyl ketone, and methyl isobutyl ketone), an ester-based solvent (e.g., ethyl formate, ethyl acetate, and n-butyl acetate), an ether-based solvent (e.g., diethyl ether, dimethoxy ethane, tetrahydrofuran, dioxolane, and dioxane), an amide-based solvent (e.g., N,N-dimethyl formamide, N,N-dimethyl acetoamide, and N-methyl-2-pyrrolidone), a halogenated hydrocarbon-based solvent (e.g., dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene), and a hydrocarbon-based solvent (e.g., n-pentane, n-hexane, n-octane, 1,5-hexadiene, cyclohexane, methylcyclohexane, cyclohexadiene, benzene, toluene, o-xylene, m-xylene, p-xylene, ethyl benzene, and cumene). These may be used alone, or as a mixed solvent by mixing two or more of them.

A coating method in the wet-film formation is not particularly limited, and can be performed in accordance with a conventional method.

As for the coating method, for example, various methods, such as dip coating, spray coating, wire-bar coating, spin coating, roller coating, blade coating, gravure coating, and wet printing (e.g., relief printing, offset printing, gravure printing, intaglio printing, rubber plate printing, and screen printing) can be used. Moreover, the film formation may be performed in a supercritical fluid, or subcritical fluid.

The supercritical fluid is appropriately selected depending on the intended purpose without any limitation, provided that it exists as a non-condensable high-pressure fluid in the temperature and pressure region exceeding the limits (critical points) where a gas and a liquid can coexist, is not condensed as being compressed, and is a fluid in the state equal to or higher the critical temperature, and equal to or higher than the critical pressure. The supercritical fluid is preferably a fluid having low critical temperature.

As for the supercritical fluid, for example, preferred are carbon monoxide, carbon dioxide, ammonia, nitrogen, water, an alcohol-based solvent (e.g., methanol, ethanol, and n-butanol), a hydrocarbon-based solvent (e.g., ethane, propane, 2,3-dimethylbutane, benzene, and toluene), a halogen-based solvent (e.g., methylene chloride, and chlorotrifluoromethane), and an ether-based solvent (e.g., dimethyl ether).

Among them, carbon dioxide is particularly preferable because the critical pressure and critical temperature of carbon dioxide are respectively about 7.4 MPa, and about 31° C., and thus a supercritical state of carbon dioxide is easily formed. In addition, carbon dioxide is non-flammable, and therefore it is easily handled.

These fluids may be used alone, or in combination.

The subcritical fluid is appropriately selected depending on the intended purpose without any limitation, provided that it is a substance that exists as a high-pressure liquid in the temperature and pressure region adjacent to the critical points.

The compounds listed as the supercritical fluid can be also suitably used as the subcritical fluid.

The critical temperature and critical pressure of the supercritical fluid are appropriately selected depending on the intended purpose without any limitation. The critical temperature is preferably −273° C. to 300° C., particularly preferably 0° C. to 200° C.

Moreover, an organic solvent, or an entrainer may be used in combination with the aforementioned supercritical fluid and subcritical fluid.

The solubility in the supercritical fluid can be easily adjusted by adding the organic solvent and the entrainer.

Such an organic solvent is appropriately selected depending on the intended purpose without any limitation, and examples thereof include ketone-based solvent, (e.g., acetone, methyl ethyl ketone, and methyl isobutyl ketone), an ester-based solvent (e.g., ethyl formate, ethyl acetate, and n-butyl acetate), an -ether-based solvent (e.g., diisopropyl ether, dimethoxy ethane, tetrahydrofuran, dioxolane, and dioxane), an amide-based solvent (e.g., N,N-dimethyl formamide, N,N-dimethyl acetoamide, and N-methyl-2-pyrrolidone), a halogenated hydrocarbon-based solvent (e.g., dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene), and a hydrocarbon-based solvent (e.g., n-pentane, n-hexane, n-octane, 1,5-hexadiene, cyclohexane, methylcyclohexane, cyclohexadiene, benzene, toluene, o-xylene, m-xylene, p-xylene, ethyl benzene, and cumene).

In the present invention, a press treatment step may be provided after providing the radox layer. The press treatment improves the efficiency for adhering the radox material to the porous electrode.

The press treatment method is not particularly limited, and examples thereof include: press molding using a plate, such as IR pellet press; and roll pressing using a roller. The pressure for the press is preferably 10 kgf/cm² or greater, more preferably 30 kgf/cm² or greater. The duration for the press treatment is not particularly limited, but it is preferred that the press treatment be performed within 1 hour. Moreover, heat may be applied during the press treatment.

Moreover, a releasing material may be provided between the press and the electrode. Examples of the releasing material include a fluororesin, such as polyethylene tetrafluoride, polychloroethylene trifluoride, an ethylene tetrafluoride-propylene hexafluoride copolymer, a perfluoroalkoxy fluorocarbon resin, polyvinylidene fluoride, an ethylene-ethylene tetrafluoride copolymer, an ethylene-chloroethylene trifluoride copolymer, and polyvinyl fluoride.

### <Hole Transport Layer>

In the present invention, the hole transport layer 8 may have a single layer structure formed of a single material, or a laminate structure formed of a plurality of compounds. In case of the laminate structure, a polymer material is used in the hole-transporting material layer 8 provided adjacent to the second electrode 9. Use of the polymer material having excellent film forming ability can level a surface of the porous electron transport layer, and can improve photoelectric conversion properties. The polymer is difficult to penetrate into the porous electron transport layer, but on the other hand, the polymer is excellent in covering a surface of the porous electron transport layer, and exhibits an effect of preventing short circuit when an electrode is provided. Therefore, the higher performance can be achieved.

As for the polymer used in the hole transport layer, hole-transporting high-molecular weight materials known in the art can be used. Specific examples thereof include: polythiophene compound, such as poly(3-n-hexylthiophene), poly(3-n-octyloxythiophene), poly(9,9′-dioctyl-fluorene-co-bithiophene), poly(3,3′″-didodecyl-quaterthiophene), poly(3,6-dioctylthieno[3,2-b]thiophene), poly(2,5-bis (3-decylthiophen-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), poly(3,6-dioctylthieno[3,2-b]thiophene-co-bithiophene); a polyphenylene vinylene compound, such as poly[2-methoxy-5-(2-ethylhexyloxy)-1,4-phenylenevinylene], poly[2-methoxy-5-(3,7-dimethyloctyloxy)-1,4-phenylenevinylene], poly[(2-methoxy-5-(2-ethylhexyloxy)-1,4-phenylenevinylene)-co-(4,4′-biphenylene-vinylene)]; a polyfluorene compound, such as poly(9,9′-didodecylfluorenyl-2,7-diyl), poly[(9,9-dioctyl-2,7-divinylenefluorene)-alt-co-(9, 10-anthracene)], poly[(9,9-dioctyl-2,7-divinylenefluorene)-alt-co-(4,4′-biphenylene)], poly[(9,9-dioctyl-2,7-divinylenefluorene)-alt-co-(2-methoxy-5-(2-ethylhexyloxy)-1,4-phenylene)], and poly[(9,9-dioctyl-2,7-diyl)-co-(1,4-(2,5-dihexyloxy)benzene)]; a polyphenylene compound, such as poly[2,5-dioctyloxy-1,4-phenylene], and poly[2,5-di(2-ethylhexyloxy-1,4-phenylene]; a polyaryl amine compound, such as poly[(9,9-dioctylfluorenyl-2,7-diyl)-alt-co-(N,N′-diphenyl)-N,N′-di (p-hexylphenyl)-1,4-diaminobenzene], poly[(9,9-dioctylfluorenyl-2,7-diyl)-alt-co-(N,N′-bis(4-octyloxyphenyl)benzidine-N,N′-(1,4-diphenylene)], poly[(N,N′-bis(4-octyloxyphenyl)benzidine-N,N′-(1,4-diphenylene)], poly[(N,N′-bis(4-(2-ethylhexyloxy)phenyl)benzidine-N,N′-(1,4-diphenylene)], poly[phenylimino-1,4-phenylenevinylene-2,5-dioctyloxy-1,4-phenylenevinylene-1,4-phenylene], poly[p-tolylimino-1,4-phenylenevinylene-2,5-di(2-ethylhexyloxy)-1,4-phenylenevinylene-1,4-phenylene], and poly[4-(2-ethylhexyloxy)phenylimino-1,4-biphenylene]; and a polythiadiazole compound, such as poly[(9,9-dioctylfluorenyl-2,7-diyl)-alt-co-(1,4-benzo(2,1′,3)thiadiazole], and poly(3,4-didecylthiophene-co-(1,4-benzo(2,1′,3)thiadiazole). Among them, the polythiophene compound and the polyaryl amine compound are particularly preferable in view of carrier mobility and ionization potential. There may be used alone, or in combination.

In the solar cell of the present invention, moreover, various additives may be added to the aforementioned hole transporting compound.

Examples of the additives include: iodine; metal iodide, such as lithium iodide, sodium iodide, potassium iodide, cesium iodide, calcium iodide, copper iodide, and iron iodide; a quaternary ammonium salt, such as tetraalkyl ammonium iodide, and pyridinium iodide; metal bromide, such as lithium bromide, sodium bromide, potassium bromide, cesium bromide, and calcium bromide; a bromine salt of a quaternary ammonium compound, such as tetraalkyl ammonium bromide, and pyridinium bromide; metal chloride, such as copper chloride, and silver chloride; an acetic acid metal salt, such as copper acetate, silver acetate, and palladium acetate; metal sulfate, such as copper sulfate, and zinc sulfate; a metal complex, such as ferrocyanic acid salt-ferricyanic acid salt, and ferrocene-ferricinium ion; a sulfur compound, such as sodium polysulfide, and alkyl thiol-alkyldisulfide; a viologen dye, and hydroquinone; an ionic liquid, such as 1,2-dimethyl-3-n-propylimidazolinium iodide, 1-methyl-3-n-hexylimidazolinium iodide, 1,2-dimethyl-3-ethylimidazolium trifluoromethane sulfonic acid salt, 1-methyl-3-butylimidazolium nonafluorobutyl sulfonic acid salt, 1-methyl-3-ethylimidazolium bis(trifluoromethyl)sulfonylimide, 1-methyl-3-n-hexylimidazolium bis(trifluoromethyl)sulfonylimide, and 1-methyl-3-n-hexylimidazolium dicyanamide; a basic compound, such as pyridine, 4-t-butylpyridine, and benzimidazole; and a lithium compound, such as lithium trifluoromethane sulfonyl imide, and lithium diisopropyl imide. Among them, the imidazolinium compound is preferable as the cation, and the additive containing bis(trifluoromethyl)sulfonylimide anion is preferable as the anion. These additives may be used alone, or in combination.

To the solar cell of the present invention, an acceptor material may be optionally further added, in addition to the aforementioned hole transporting compound and various additives.

Examples of the acceptor material include chloranil, bromanil, tetracyanoethylene, tetracyanoquinodimethane, 2,4,7-trinitro-9-fluorenon, 2,4,5,7-tetranitro-9-fluorenon, 2,4,5,7-tetranitroxanthone, 2,4,8-trinitrothioxanthone, 2,6,8-trinitro-4H-indeno[1,2-b]thiophen-4-one, 1,3,7-trinitrobenzothiophene-5,5-dioxide, and a diphenoquinone derivative. These acceptor materials may be used alone, or in combination.

In order to improve electroconductivity, an oxidizing agent, which transforms part of the hole transporting compound to a radical cation, may be added.

Examples of the oxidizing agent include tris(4-bromophenyl)ammoniumyl hexachloroantimonate, silver hexafluoroantimonate, nitrosonium tetrafluoroborate, and silver nitrate.

It is not necessary to oxidize the entire hole-transporting material as a result of the addition of the oxidizing agent, as long as part of the hole-transporting material is oxidized by the addition of the oxidizing agent. Moreover, the added oxidizing agent may be taken out from the system, or be left in the system after the addition thereof.

The hole transport layer 8 is formed directly on the charge transfer layer 7.

A formation method of the hole transport layer is not particularly limited, and examples thereof include: a method for forming a thin film in vacuum, such as vacuum deposition; and a wet film forming method. In view of the production cost, the wet film forming method is particularly preferable, and a method for coating on the electron transport layer is preferable. In the case where the wet film forming method is used, examples of the solvent, in which the hole transporting compound and various additives are dissolved or dispersed, include those listed as the examples in the descriptions of the formation of the charge transfer layer.

Moreover, a supercritical fluid can be used also in the formation of the hole transport layer. Specific examples thereof include those listed as the examples in the descriptions of the formation of the charge transfer layer. Examples of the organic solvent and entrainer are also the same as those listed above.

In the present invention, a press treatment step is provided after providing the hole transport layer. The press treatment improves the efficiency for adhering the hole-transporting material to the charge transfer layer. Specific examples of the press treatment method include those listed as the examples in the descriptions of the charge transfer layer.

A metal oxide may be provided between the hole transporting compound and the second electrode, after performing the press treatment step, but before providing the counter electrode. Examples of the metal oxide to be provided include molybdenum oxide, tungsten oxide, vanadium oxide, and nickel oxide. Among them, molybdenum oxide is particularly preferable.

### <Hole Collecting Electrode>

A method for providing any of these metal oxides on the hole-transporting material is not particularly limited, and examples thereof include: a method for forming a thin film in vacuum, such as sputtering and vacuum deposition; and a wet film forming method.

The wet film forming method is preferably a method, where a paste, in which a powder or sol of the metal oxide is dispersed, is prepared, and the paste is then applied on the hole transport layer through coating.

In the case where the wet film forming method is used, a coating method is not particularly limited, and the coating can be carried out in accordance with any of conventional methods.

For example, various methods, such as dip coating, spray coating, wire-bar coating, spin coating, roller coating, blade coating, gravure coating, and a wet printing method (e.g., relief printing, offset printing, gravure printing, intaglio printing, rubber plate printing, and screen printing) can be used. A thickness thereof is preferably 0.1 nm to 50 nm, and more preferably 1 nm to 10 nm.

The hole-collecting electrode is separately provided after the formation of the hole transport layer, or on the aforementioned metal oxide.

As for the hole-collecting electrode, moreover, the one used as the aforementioned electron-collecting electrode can be generally used. The substrate may be unnecessary in the structure of the hole-collecting electrode where the strength or sealing performance is sufficiently secured.

Specific examples of the hole-collecting electrode material include a metal (e.g., platinum, gold, silver, copper, and aluminum), a carbon-based compound (e.g., graphite, fullerene, carbon nanotube, and grapheme), an electroconductive metal oxide (e.g., ITO, FTO, and ATO), and an electroconductive polymer (e.g., polythiophene, and polyaniline).

A thickness of the hole-collecting electrode layer is not particularly limited. The hole-collecting electrode may be a single layer, or a multilayer.

The hole-collecting electrode can be appropriately formed on the hole transport layer by coating, laminating, vapor deposition, CVD, or bonding, depending on materials for use, or a type of the hole transport layer.

In order to function as a photoelectric conversion element, at least either the electron-collecting electrode or the hole-collecting electrode needs to be substantially transparent.

In the solar cell of the present invention, it is preferred that the side of the electron-collecting electrode be transparent, and sun light be introduced from the side of the electron-collecting electrode. In this case, a material that reflects light is preferably used at the side of the hole-collecting electrode. As for such a material, glass or plastic to which a metal or electroconductive oxide is deposited, or a metal thin film is preferable.

Moreover, it is also effective to provide an antireflection layer at the side from which sun light enters.

### <Use>

The solar cell of the present invention can be applied for a power supply device.

As an applied example, any application can be realized as long as it is a conventional device utilizing the solar cell or a power supply device using the solar cell.

For example, the solar cell of the present invention can be used as a solar cell for an electronic calculator, or watch. Applied examples of the solar cell of the present invention include a power supply device for a mobile phone, a power supply device for an electronic organizer, and a power supply device for electronic paper. Moreover, the solar cell of the present invention can be used as auxiliary power for extending a period of a continuous use of a rechargeable, or dry battery-loaded electric appliance.

### EXAMPLES

The present invention is more specifically explained through Examples hereinafter, but the embodiments of the present invention are not limited to Examples below.

### Synthesis Examples of Metal Complex for Use in the Present Invention

### Synthesis Example 1

### Synthesis of tris(2,2′-bipyridyl)cobalt (II) perchlorate

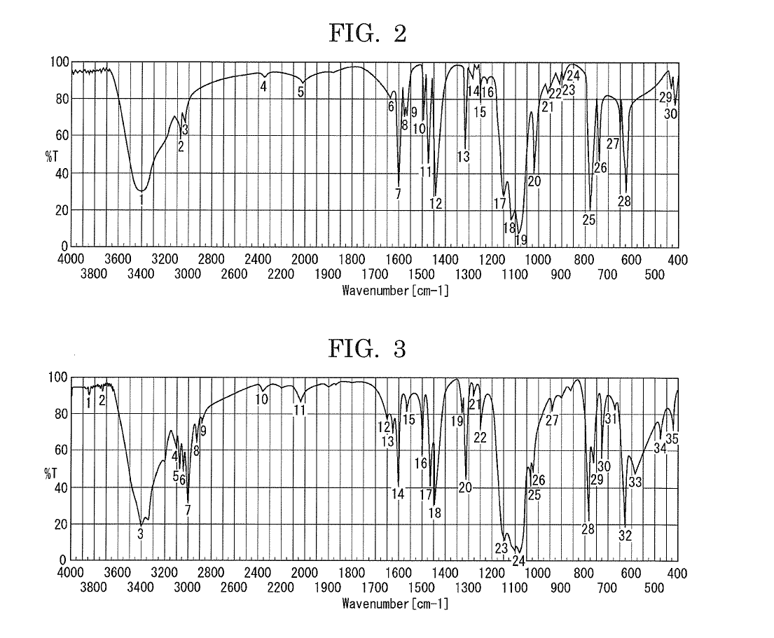

Cobalt perchlorate hexahydrate (0.50 g), and 2,2′-bipyridine (0.64 g) were heated and stirred at 60° C. together with water (6 mL). When the entire solids were dissolved, the resulting solution was cooled to room temperature, followed by removing water through vacuum distillation. The residue was purified by repeating a reprecipitation process where the residue was dissolved in methanol, and the resulting solution was poured into diethyl ether, to thereby obtain a target (0.93 g). The yield was 93.5%. The IR spectrum of the obtained compound was depicted in FIG. 2.

### Synthesis Example 2

### Synthesis of Tris(2,2′-Bipyridyl)cobalt (III) Perchlorate

Cobalt perchlorate hexahydrate (0.50 g), and 2,2′-bipyridine (0.64 g) were heated and stirred at 60° C. together with methanol (6 mL). When the entire solids were dissolved, lithium perchlorate (0.72 g) was added, and then a mixture of hydrogen peroxide water (0.70 g) and water (1.3 g) was further added.

Ten minutes later, the reaction was terminated, and the solvent was removed through vacuum distillation. The residue was purified by repeating a reprecipitation process where the residue was dissolved in methanol, and the resulting solution was poured into diethyl ether, to thereby obtain a target (0.91 g). The yield was 80.4%.

The IR spectrum of the obtained compound is depicted in FIG. 3.

### Synthesis Example 3

### Synthesis of tris(2,2′-bipyridyl)cobalt (II) tetracyanoborate

Cobalt chloride hexahydrate (0.50 g), and 2,2′-bipyridine (0.98 g) were heated and stirred at 60° C. together with water (10 mL). When the entire solids were dissolved, water was removed through vacuum distillation. Methanol (10 mL) was added to the residue to dissolve. To the resultant, 1-ethyl-2-methylimidazolinium tetracyanoborate (2.85 g) was added, and the mixture was heated and stirred at 60° C. Ten minutes later, the reaction was terminated, and the solvent was removed through vacuum distillation.

The residue was purified by repeating a reprecipitation process where the residue was dissolved in methanol, and the resulting solution was poured into water, to thereby obtain a target (1.44 g). The yield was 90.6%. The IR spectrum of the obtained compound was depicted in FIG. 4.

### Synthesis Example 4

### Synthesis of tris(2,2′-bipyridyl)cobalt (III) tetracyanoborate

Cobalt chloride hexahydrate (0.50 g) and 2,2′-bipyridine (0.98 g) were heated and stirred at 60° C. together with water (10 mL). When the entire solids were dissolved, hydrogen peroxide water (2 mL) and concentrated hydrochloric acid (1 mL) were added with stirring at room temperature. Ten minutes later, the reaction liquid was removed through vacuum distillation. Methanol (10 mL) was added to the residue and dissolved the residue therein. To the resultant, 1-ethyl-2-methylimidazolinium tetracyanoborate (2.85 g) was added, and the mixture was then heated and stirred at 60° C. Ten minutes later, the reaction was terminated, and the solvent was removed through vacuum distillation.

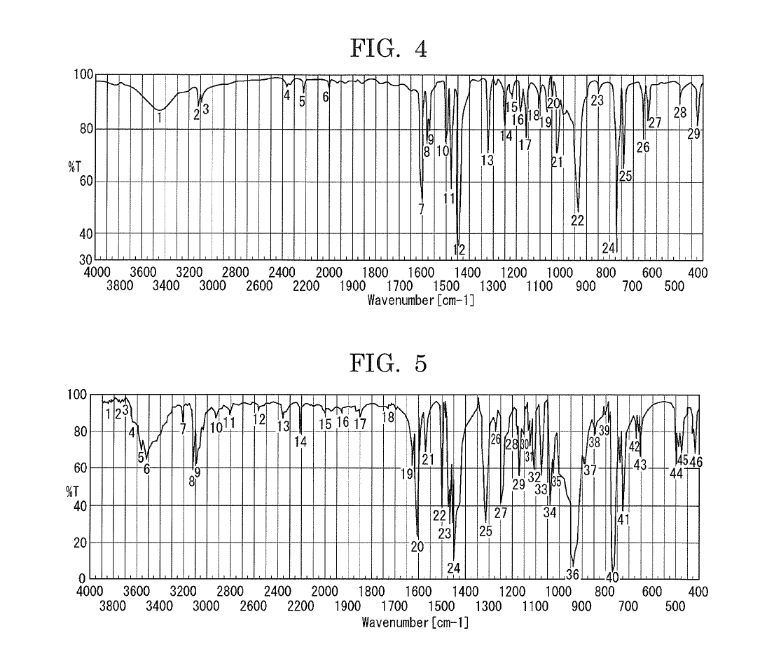

The residue was purified by repeating a reprecipitation process where the residue was dissolved in methanol, and the resulting solution was poured into water, to thereby obtain a target (1.06 g). The yield was 57.9%. The IR spectrum of the obtained compound is depicted in FIG. 5.

### Example 1

### Preparation of Titanium Oxide Semiconductor Electrode

Titanium tetra-n-propoxide (2 mL), acetic acid (4 mL), ion-exchanged water (1 mL), and 2-propanol (40 mL) were mixed, and the resulting mixture was applied on a FTO glass substrate by spin coating. The resultant was dried at room temperature, followed by baking in the air at 450° C. for 30 minutes. The same mixture (solution) was again applied on the obtained electrode by spin coating so that a thickness thereof was to be 100 nm, and the resultant was baked in the air at 450° C. for 30 minutes, to thereby form a dense electron transport layer.

Together with 5.5 g of water and 1.0 g of ethanol, 3 g of titanium oxide (ST-21, manufactured by ISHIHARA SANGYO KAISHA, LTD.), 0.2 g of acetyl acetone, and 0.3 g of a surfactant (polyoxyethylene octylphenyl ether, manufactured by Wako Pure Chemical Industries, Ltd.) were treated by means of a bead mill for 12 hours.

Polyethylene glycol (#20,000) (1.2 g) was added to the obtained dispersion liquid, to thereby prepare a paste.

The paste was applied onto the dense electron transport layer in the manner that the paste gave a thickness of 2 μm, and then was dried at room temperature. Thereafter, the dried paste was backed in the air at 500° C. for 30 minutes, to thereby form a porous electron transport layer.

### (Production of Dye-Sensitized Solar Cell)

The above-obtained titanium oxide semiconductor electrode was immersed in, as a sensitizing dye, D358 (0.5 mM, acetonitrile/t-butanol (volume ratio 1:1) solution) manufactured by Mitsubishi Paper Mills Limited, and then was left to stand in the dark for 1 hour, to thereby adsorb the photosensitizing compound.

On the semiconductor electrode to which the photosensitizer was carried, a 2-methoxyethanol solution (1.0 mL), in which tris(2,2′-bipyridyl)cobalt (II) perchlorate (14.2 mg), tris(2,2′-bipyridyl)cobalt (III) perchlorate (2.5 mg), 1-n-hexyl-2-methylimidazolinium bis(trifluoromethane sulfonyl)imide (27.3 mg), lithium perchlorate (30.4 mg), and 4-t-butyl pyridine (0.7 mg) were dissolved, was applied by spin coating to form a film. The film was then air dried.

Subsequently, a solution prepared by adding lithium bis(trifluoromethane sulfonyl)imide (27 mM) to a chlorobenzene solution (solid content: 2%), in which poly(3-n-hexylthiophene) manufactured by Sigma-Aldrich Japan K.K. was dissolved, was applied by spray coating, to thereby form a thin film having a thickness of about 100 nm. On this film, silver was deposited by vapor deposition to form a layer of about 100 nm, to thereby produce a solid dye-sensitized solar cell.

### (Evaluation of Dye-Sensitized Solar Cell)

The photoelectric conversion efficiency of the obtained dye-sensitized solar cell was measured upon application of simulated solar light (AM 1.5, 100 mW/cm²). The simulated solar light was applied by a solar simulator SS-80XIL manufactured by EKO Instruments, and the measurement was performed by using a solar cell evaluation system As-510-PV03 manufactured by NF Corporation as an evaluation device. As a result, the dye-sensitized solar cell exhibited excellent properties that the open circuit voltage was 0.70 V, the short circuit current density was 6.40 mA/cm², the form factor was 0.70, and the conversion efficiency was 3.14%.

### Example 2

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-bipyridyl)cobalt (II) hexafluorophosphate (14.2 mg) and tris(2,2′-bipyridyl)cobalt (III) hexafluorophosphate (2.5 mg), as depicted in Table 1. The results are presented in Table 1.

TABLE 1

| | | | Short | | |
|---|---|---|---|---|---|
| | | Open | circuit | | |
| | | circuit | current | | Conversion |
| | | voltage | density | Form | efficiency |
| Ex. | Metal complex | [V] | [mA/cm²] | factor | [%] |
| 1 | Tris(2,2′-bipyridyl)cobalt(II) perchlorate | 0.7 | 6.4 | 0.7 | 3.14 |
| | (14.2 mg)/ | | | | |
| | Tris(2,2′-bipyridyl)cobalt(III) | | | | |
| | perchlorate (2.5 mg) | | | | |
| 2 | Tris(2,2′-bipyridyl)cobalt(II) | 0.71 | 6.13 | 0.71 | 3.09 |
| | hexafluorophosphate (14.2 mg)/ | | | | |
| | Tris(2,2′-bipyridyl)cobalt(III) | | | | |
| | hexafluorophosphate (2.5 mg) | | | | |
| 3 | Tris(2,2′-bipyridyl)cobalt(II) | 0.72 | 5.92 | 0.7 | 2.98 |
| | tetrafluoroborate (14.2 mg)/ | | | | |
| | Tris(2,2′-bipyridyl)cobalt(III) | | | | |
| | tetrafluoroborate (2.5 mg) | | | | |
| 4 | Tris(2,2′-bipyridyl)cobalt(II) perchlorate | 0.69 | 6.25 | 0.69 | 2.98 |
| | (18.4 mg)/ | | | | |
| | Tris(2,2′-bipyridyl)cobalt(III) | | | | |
| | perchlorate (3.6 mg) | | | | |
| 5 | Tris(2,2′-bipyridyl)cobalt(II) perchlorate | 0.68 | 6.24 | 0.69 | 2.93 |
| | (18.4 mg)/ | | | | |
| | Tris(2,2′-bipyridyl)cobalt(III) | | | | |
| | perchlorate (2.5 mg) | | | | |
| 6 | Tris(2,2′-4,4′-n-octylbipyridyl)cobalt(II) | 0.72 | 6.8 | 0.68 | 3.33 |
| | perchlorate (14.2 mg)/ | | | | |
| | Tris(2,2′-4,4′-n-octylbipyridyl)cobalt(III) | | | | |
| | perchlorate (2.5 mg) | | | | |
| 7 | Tris(2,2′-4,4′-n-octylbipyridyl)cobalt(II) | 0.73 | 5.99 | 0.69 | 3.02 |
| | tetrafluoroborate (14.2 mg)/ | | | | |
| | Tris(2,2′-4,4′-n-octylbipyridyl)cobalt(III) | | | | |
| | tetrafluoroborate (2.5 mg) | | | | |
| 8 | Tris(2-benzothiazolylpyridyl)cobalt(II) | 0.72 | 5.86 | 0.68 | 2.87 |
| | perchlorate (14.2 mg)/ | | | | |
| | Tris(2-benzothiazolylpyridyl)cobalt(III) | | | | |
| | perchlorate (2.5 mg) | | | | |
| 9 | Tris(2,2′-bipyridyl)cobalt(II) | 0.69 | 6.01 | 0.69 | 2.86 |
| | tetracyanoborate (14.2 mg)/ | | | | |
| | Tris(2,2′-bipyridyl)cobalt(III) | | | | |
| | tetracyanoborate perchlorate (2.5 mg) | | | | |
| 10 | Tris(2,2′-4,4′-n-octylbipyridyl)cobalt(II) | 0.71 | 6.33 | 0.68 | 3.06 |
| | tetracyanoborate (14.2 mg)/ | | | | |
| | Tris(2,2′-4,4′-n-octylbipyridyl)cobalt(III) | | | | |
| | tetracyanoborate (2.5 mg) | | | | |
| 11 | Tris(2,2′-4,4′-n-octylbipyridyl)cobalt(II) | 0.7 | 6.35 | 0.68 | 3.07 |
| | tetracyanoborate (18.4 mg)/ | | | | |
| | Tris(2,2′-4,4′-n-octylbipyridyl)cobalt(III) | | | | |
| | tetracyanoborate (3.6 mg) | | | | |
| 12 | Tris(2,2′-4,4′-n-octylbipyridyl)cobalt(II) | 0.71 | 6.18 | 0.69 | 3.03 |
| | tetracyanoborate (18.4 mg)/ | | | | |
| | Tris(2,2′-4,4′-n-octylbipyridyl)cobalt(III) | | | | |
| | tetracyanoborate (2.5 mg) | | | | |

### Example 3

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-bipyridyl)cobalt (II) tetrafluoroborate (14.2 mg) and tris(2,2′-bipyridyl)cobalt (III) tetrafluoroborate (2.5 mg), as depicted in Table 1. The results are presented in Table 1.

### Example 4

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-bipyridyl)cobalt (II) perchlorate (18.4 mg) and tris(2,2′-bipyridyl)cobalt (III) perchlorate (3.6 mg), as depicted in Table 1. The results are presented in Table 1.

### Example 5

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-bipyridyl)cobalt (II) perchlorate (18.4 mg) and tris(2,2′-bipyridyl)cobalt (III) perchlorate (2.5 mg), as depicted in Table 1. The results are presented in Table 1.

### Example 6

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-4,4′-n-octylbipyridyl)cobalt (II) perchlorate (14.2 mg) and tris(2,2′-4,4′-n-octylbipyridyl)cobalt (III) perchlorate (2.5 mg), as depicted in Table 1. The results are presented in Table 1.

### Example 7

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-4,4′-n-octylbipyridyl)cobalt (II) tetrafluoroborate (14.2 mg) and tris(2,2′-4,4′-n-octylbipyridyl)cobalt (III) tetrafluoroborate (2.5 mg), as depicted in Table 1. The results are presented in Table 1.

### Example 8

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2-benzothiazolylpyridyl)cobalt (II) perchlorate (14.2 mg) and tris(2-benzothiazolylpyridyl)cobalt (III) perchlorate (2.5 mg), as depicted in Table 1. The results are presented in Table 1.

### Example 9

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-bipyridyl)cobalt (II) tetracyanoborate (14.2 mg) and tris(2,2′-bipyridyl)cobalt (III) tetracyanoborate perchlorate (2.5 mg), as depicted in Table 1. The results are presented in Table 1.

### Example 10

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-4,4′-n-octylbipyridyl)cobalt (II) tetracyanoborate (14.2 mg) and tris(2,2′-4,4′-n-octylbipyridyl)cobalt (III) tetracyanoborate (2.5 mg), as depicted in Table 1. The results are presented in Table 1.

### Example 11

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-4,4′-n-octylbipyridyl)cobalt (II) tetracyanoborate (18.4 mg) and tris(2,2′-4,4′-n-octylbipyridyl)cobalt (III) tetracyanoborate (3.6 mg), as depicted in Table 1. The results are presented in Table 1.

### Example 12

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-4,4′-n-octylbipyridyl)cobalt (II) tricyanoborate (18.4 mg) and tris(2,2′-4,4′-n-octylbipyridyl)cobalt (III) tricyanoborate (2.5 mg), as depicted in Table 1. The results are presented in Table 1.

As clearly seen in Table 2, all of the metal complexes exhibited excellent properties. Among them, the mixture of tris(2,2′-4,4′-n-octylbipyridyl)cobalt (II) tetrafluoroborate and tris(2,2′-4,4′-n-octylbipyridyl)cobalt (III) tetrafluoroborate exhibited particularly excellent properties.

### Example 13

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-bipyridyl)cobalt (II) perchlorate (14.2 mg) and tris(2,2′-bipyridyl)iron (III) perchlorate (2.5 mg). The results are presented in Table 2.

### Example 14

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were tris(2,2′-bipyridyl)cobalt (II) perchlorate (14.2 mg) and tris(2,2′-bipyridyl)nickel (III) perchlorate (2.5 mg). The results are presented in Table 2.

### Example 15

A dye-sensitized solar cell was produced and evaluated in the same manner as in Example 1, provided that the cobalt complexes that were tris(2,2′-bipyridyl)cobalt (II) perchlorate (14.2 mg) and tris(2,2′-bipyridyl)cobalt (III) perchlorate (2.5 mg) were replaced with metal complexes that were bis(2,2′-bipyridyl)copper(II) perchlorate (14.2 mg) and tris(2,2′-bipyridyl)cobalt (III) perchlorate (2.5 mg). The results are presented in Table 2.

It was found from Examples 13 to 15 that excellent properties could be attained by blending the metal complex other than the cobalt complex, through the properties were slightly lower than when the cobalt complexes were used.

### Example 16

A dye-sensitized solar cell was produced and evaluated in the same manner as in Example 1, provided that the titanium oxide (3 g) was replaced with zinc oxide (3 g) manufactured by C. I. KASEI CO., LTD. The results are presented in Table 2.

### Example 17

A dye-sensitized solar cell was produced and evaluated in the same manner as in Example 1, provided that the titanium oxide (3 g) was replaced with tin oxide (3 g) manufactured by C. I. KASEI CO., LTD. The results are presented in Table 2.

### Example 18

A dye-sensitized solar cell was produced and evaluated in the same manner as in Example 1, provided that the titanium oxide (3 g) was replaced with a mixture of titanium oxide (2 g) and niobium (V) oxide (1 g). The results are presented in Table 3.

It was found from Examples 16 to 18 that excellent properties could be attained by using the oxide other than titanium oxide, even through the properties were slightly lower compared to a solo use of titanium oxide.

### Example 19

A dye-sensitized solar cell was produced and evaluated in the same manner as in Example 1, provided that the formation of the hole transport layer (the thin film of about 100 nm was formed by applying the solution prepared by adding lithium bis(trifluoromethane sulfonyl)imide (27 mM) to the chlorobenzene solution (solid content: 2%), in which poly(3-n-hexylthiophene) manufactured by Sigma-Aldrich Japan K.K. was dissolved, through spray coating) was changed as follows. The results are presented in Table 2. Changes: an acetnitrile (solid content: 2%) solution, in which copper iodide manufactured by Sigma-Aldrich Japan K.K. had been dissolved, was applied by spray coating to thereby form a thin film having a thickness of about 100 nm.

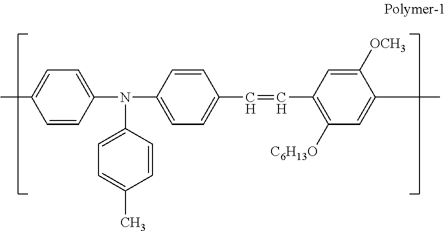

### Example 20

A dye-sensitized solar cell was produced and evaluated in the same manner as in Example 1, provided that the formation of the hole transport layer (the thin film of about 100 nm was formed by applying the solution prepared by adding lithium bis(trifluoromethane sulfonyl)imide (27 mM) to the chlorobenzene solution (solid content: 2%), in which poly(3-n-hexylthiophene) manufactured by Sigma-Aldrich Japan K.K. was dissolved, through spray coating) was changed as follows. The results are presented in Table 2. Changes: A solution obtained by adding lithium bis(trifluoromethane sulfonyl) imide (2.7 mM) to a chlorobenzene solution (solid content: 2%), in which Polymer 1 synthesized by us, and depicted in Table 2 was dissolved, was applied through spray coating, to thereby form a thin film of about 50 nm. On the formed film, a solution obtained by adding lithium bis(trifluoromethane sulfonyl) imide (2.7 mM) to a chlorobenzene solution (solid content: 2%), in which poly(3-n-hexylthiophene) manufactured by Sigma-Aldrich Japan K.K. was dissolved, was applied through spray coating, to thereby form a thin film of about 50 nm.

It was confirmed from Examples 19 and 20 that the solar cell functioned even when the oxide other than titanium oxide was used, through properties thereof were lower than those of the solar cell using P3HT.

TABLE 2

| | | | Short | | |
|---|---|---|---|---|---|
| | | Open | circuit | | |
| | | circuit | current | | Conversion |
| | | voltage | density | Form | efficiency |
| Ex. | Changes | [V] | [mA/cm²] | factor | [%] |
| 13 | Metal complex: tris(2,2′-bipyridyl)cobalt | 0.66 | 5.97 | 0.68 | 2.68 |
| | (II) perchlorate (14.2 mg)/ | | | | |
| | tris(2,2′-bipyridyl)cobalt (III) | | | | |
| | perchlorate (2.0 mg)/ | | | | |
| | tris(2,2′-bipyridyl)iron (III) perchlorate | | | | |
| | (0.5 mg) | | | | |
| 14 | Metal complex: tris(2,2′-bipyridyl)cobalt | 0.69 | 5.81 | 0.69 | 2.77 |
| | (II) perchlorate (14.2 mg)/ | | | | |
| | tris(2,2′-bipyridyl)cobalt (III) | | | | |
| | perchlorate (2.0 mg)/ | | | | |
| | tris(2,2′-bipyridyl) nickel (III) | | | | |
| | perchlorate (0.5 mg) | | | | |
| 15 | Metal complex: tris(2,2′-bipyridyl)cobalt | 0.72 | 6.04 | 0.67 | 2.91 |
| | (II) perchlorate (14.2 mg)/ | | | | |
| | tris(2,2′-bipyridyl)cobalt (III) | | | | |
| | perchlorate (2.0 mg)/ | | | | |
| | tris(2,2′-bipyridyl)copper (III) | | | | |
| | perchlorate (0.5 mg) | | | | |
| 16 | Electron transporting compound: zinc | 0.67 | 6.22 | 0.68 | 2.83 |
| | oxide | | | | |
| 17 | Electron transporting compound: tin | 0.67 | 6.18 | 0.69 | 2.86 |
| | oxide | | | | |
| 18 | Electron transporting compound: | 0.71 | 5.94 | 0.68 | 2.87 |
| | titanium oxide/niobium oxide | | | | |
| 19 | Hole transport layer: copper iodide | 0.67 | 6.01 | 0.67 | 2.7 |
| 20 | Hole transport layer: laminate of | 0.75 | 5.67 | 0.68 | 2.88 |
| | Polymer 1/P3HT | | | | |

### Comparative Example 1

A dye-sensitized solar cell was prepared by bonding together the semiconductor electrode carrying the photosensitizer produced in the same manner as in Example 1, and an FTO substrate to which Pt was deposited by sputtering, and injecting the following electrolyte between the electrodes. The produced dye-sensitized solar cell was evaluated in the same manner as in Example 1. As a result, the values of the properties thereof were lower than those of Example 1. Specifically, the open circuit voltage was 0.64 V, the short circuit current density was 5.72 mA/cm², the form factor was 0.61, and the conversion efficiency was 2.23%.

Electrolyte: An acetonitrile/valeronitrile (volume ratio: 17/3) solution, in which tris(2,2′-bipyridyl)cobalt (II) perchlorate (0.2 M), tris(2,2′-bipyridyl)cobalt (III) perchlorate (0.03 M), lithium perchlorate (0.1 M), and 4-t-butylpyridine (0.05 M) are dissolved

### Comparative Example 2

A dye-sensitized solar cell was prepared by bonding together the semiconductor electrode carrying the photosensitizer produced in the same manner as in Example 1, and an FTO substrate to which Pt was deposited by sputtering, and injecting the following electrolyte between the electrodes. The produced dye-sensitized solar cell was evaluated in the same manner as in Example 1. As a result, the values of the properties thereof were lower than those of Example 1. Specifically, the open circuit voltage was 0.34 V, the short circuit current density was 1.97 mA/cm², the form factor was 0.46, and the conversion efficiency was 0.31%.

Electrolyte: An acetonitrile/valeronitrile (volume ratio: 17/3) solution, in which tris(2,2′-bipyridyl)cobalt (II) tetrafluoroborate (0.2 M), tris(2,2′-bipyridyl)cobalt (III) tetrafluoroborate (0.03 M), lithium tetrafluoroborate (0.1 M), and 4-t-butylpyridine (0.05 M) are dissolved

### Example 21

A dye-sensitized solar cell produced in the same manner as in Example 1 was left to stand in a hot air dryer set to 80° C. for 500 hours. Then, the solar cell was evaluated in the same manner as in Example 1. The conversion efficiency of the solar cell after being left to stand at 80° C. for 500 hours maintained 94% of the conversion efficiency of the solar cell before being left to stand. Therefore, it was found that the solar cell had high durability.

### Comparative Example 3

A dye-sensitized solar cell produced in the same manner as in Comparative Example 1 was left to stand in a hot air dryer set to 80° C. for 500 hours. Then, the solar cell was evaluated in the same manner as in Comparative Example 1. The conversion efficiency of the solar cell after being left to stand at 80° C. for 500 hours was reduced to 11% of the conversion efficiency of the solar cell before being left to stand. It was therefore found that the solar cell had low durability compared to the solar cell of the present invention.

The electroconductivity of the dye-sensitized solar cell of the present invention is improved, as a concentration of the metal complex salt in the charge transfer layer is high, which is because the solvent is vaporized after forming a film through spin coating the solution containing the metal complex salt. It is assumed, as a result of this, that the conversion efficiency thereof is improved. As it is clear from above, the solar cell of the present invention exhibits excellent photoelectric conversion properties and durability.

The embodiments of the present invention are as follows:

<1> A dye-sensitized solar cell, containing:

a transparent electroconductive film substrate;

a first electrode provided with a layer of an electron-transporting compound, which is composed of nano particles each coated with a sensitizing dye;

a charge transfer layer;

a hole transport layer; and

a second electrode,

wherein the first electrode, the charge transfer layer, the hole transport layer, and the second electrode are provided in this order on the transparent electroconductive film substrate, and

wherein the charge transfer layer contains a metal complex salt, and the hole transport layer contains a polymer.

<2> The dye-sensitized solar cell according to <1>, wherein a metal of the metal complex salt is cobalt, iron, nickel, or copper.
<3> The dye-sensitized solar cell according to <1> or <2>, wherein the metal complex salt is a cobalt complex salt.

According to the structures specified in <2> and <3>, a solar cell having excellent cost performance and exhibiting excellent photoelectric conversion efficiency in addition to the aforementioned “Advantageous Effects of Invention” is provided.

<4> The dye-sensitized solar cell according to any one of <1> to <3>, wherein the electron-transporting compound is an oxide semiconductor.
<5> The dye-sensitized solar cell according to any one of <1> to <4>, wherein the oxide semiconductor is titanium oxide, zinc oxide, tin oxide, niobium oxide, or any combination thereof.

According to the structures specified in <4> and <5>, electron transfer becomes efficient, as an oxide semiconductor is used for the electron transport layer, and thus a solar cell exhibiting more excellent conversion efficiency is provided.

<6> The dye-sensitized solar cell according to any one of <1> to <5>, wherein the hole transport layer contains an ionic liquid.
<7> The dye-sensitized solar cell according to <6>, wherein the ionic liquid is an imidazolinium compound.

According to the structures specified in <6> and <7>, hole transfer of the hole transport layer becomes efficient, and thus a solar cell exhibiting more excellent conversion efficiency is provided.

### REFERENCE SIGNS LIST

1: substrate
2: first electrode
3: dense electron transport layer
4: particulate electron transport layer
5: electron transport layer
6: photosensitizing compound
7: charge transfer layer
8: hole transport layer
9: second electrode
10, 11: lead wire

1. A dye-sensitized solar cell, comprising:
a transparent electroconductive film substrate;
a first electrode provided with a layer of an electron-transporting compound, which is composed of nano particles each coated with a sensitizing dye;
a charge transfer layer;
a hole transport layer; and
a second electrode,
wherein the first electrode, the charge transfer layer, the hole transport layer, and the second electrode are provided in this order on the transparent electroconductive film substrate, and
wherein the charge transfer layer contains a metal complex salt, and the hole transport layer contains a polymer.

2. The dye-sensitized solar cell according to claim 1, wherein a metal of the metal complex salt is cobalt, iron, nickel, or copper.

3. The dye-sensitized solar cell according to claim 1, wherein the metal complex salt is a cobalt complex salt.

4. The dye-sensitized solar cell according to claim 1, wherein the electron-transporting compound is an oxide semiconductor.

5. The dye-sensitized solar cell according to claim 1, wherein the oxide semiconductor is titanium oxide, zinc oxide, tin oxide, niobium oxide, or any combination thereof.

6. The dye-sensitized solar cell according to claim 1, wherein the hole transport layer contains an ionic liquid.

7. The dye-sensitized solar cell according to claim 6, wherein the ionic liquid is an imidazolinium compound.
